(19) United States
(12) Patent Application Publication
(10) Pub. No.: US 2010/0059108 A1
(43) Pub. Date: Mar. 11, 2010

(54) OPTICAL SYSTEM FOR BIFACIAL SOLAR CELL

(76) Inventors: Mark McDonald, Milpitas, CA (US); Michael Ludowise, San Jose, CA (US)

Correspondence Address: BUCKLEY, MASCHOFF & TALWALKAR LLC, 50 LOCUST AVENUE, NEW CANAAN, CT, 06840, US

(21) Appl. No.: 12/206,034

(22) Filed: Sep. 8, 2008

(51) Int. Cl. H01L 31/00

(52) U.S. Cl. 136/255

(57) ABSTRACT

An apparatus and a method for its fabrication. The device may include a bifacial solar cell comprising a partially-transparent first surface and a partially-transparent second surface opposite the first surface, and an optical element comprising a first partially-transparent dielectric portion in contact with the first surface and the second surface. The optical element may be configured to receive light, to direct a first portion of the received light to the first surface, and to direct a second portion of the received light to the second surface.

### BACKGROUND

1. Field

Some embodiments generally relate to the conversion of sunlight to electric current. More specifically, embodiments may relate to improved optical systems for use in conjunction with bifacial solar cells.

2. Brief Description

A solar cell includes photovoltaic material for generating charge carriers (i.e., holes and electrons) in response to received photons. The photovoltaic material includes a p-n junction which creates an electric field within the photovoltaic material. The electric field directs the generated charge through the photovoltaic material and to elements electrically coupled thereto.

Many types of solar cells are known, which may differ from one another in terms of constituent materials, structure and/or fabrication methods. A solar cell may be selected for a particular application based on factors such as its efficiency, electrical characteristics, physical characteristics and/or cost. Attempts to improve one or more of these factors include increasing a number of p-n junctions within a solar cell (e.g., a multijunction solar cell) and allowing a solar cell to absorb light incident on either of two opposing surfaces (e.g., a bifacial solar cell).

It has also been proposed to direct light to a solar cell using a concentrating solar radiation collector. Concentrating solar radiation collectors may increase the output of any solar cell for a given amount of semiconductor material. Generally, a concentrating solar radiation collector receives solar radiation (i.e., sunlight) over a first surface area and directs the received sunlight to an active area of a solar cell. The active area of the solar cell is several times smaller than the first surface area, yet receives substantially all of the photons received by first surface area. The solar cell may thereby provide an electrical output equivalent to that of a solar cell which receives non-concentrated sunlight onto an active area the size of the first surface area.

Systems to further improve the suitability of solar power for a given deployment environment are desired.

### BRIEF DESCRIPTION OF THE DRAWINGS

The construction and usage of embodiments will become readily apparent from consideration of the following specification as illustrated in the accompanying drawings, in which like reference numerals designate like parts.

FIG. 1 is a cross-sectional side view of an apparatus according to some embodiments.

FIG. 2 is a cutaway plan view of a solar cell according to some embodiments.

FIG. 3 is a cutaway plan view of a solar cell according to some embodiments.

FIG. 4 is a partial cross-sectional side view of an apparatus according to some embodiments.

FIG. 5 is a partial cross-sectional side view of an apparatus according to some embodiments.

FIG. 6 is a partial cross-sectional side view of an apparatus according to some embodiments.

FIG. 7 is a close-up perspective view of an apparatus according to some embodiments.

### DETAILED DESCRIPTION

The following description is provided to enable any person in the art to make and use the described embodiments and sets forth the best mode contemplated by for carrying out some embodiments. Various modifications, however, will remain readily apparent to those in the art.

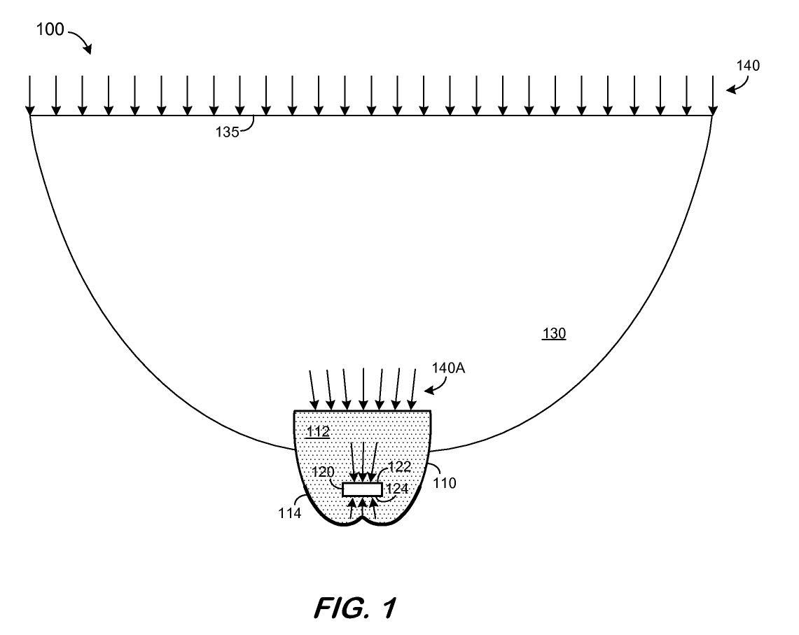

FIG. 1 is a cross-sectional side view of apparatus 100 according to some embodiments. Apparatus 100 includes optical element 110, bifacial solar cell 120 and concentrating solar collector 130. Concentrating solar collector 130 may comprise any suitable system that is or becomes known. According to some embodiments, collector 130 comprises a cassegrain-type reflector.

In operation, concentrating solar collector 130 receives light 140 at surface 135, concentrates the received light, and directs the concentrated light 140A to optical element 110. Optical element 110 directs a first portion of light 140A to first surface 122 of solar cell 120 and a second portion of light 140A to second surface 124 of solar cell 120. Solar cell 120 then converts the received light to electrical current and may transmit the current to external circuitry (not shown).

Optical element 110 may comprise partially-transparent dielectric portion 112 and reflective surface 114. Portion 112 may be at least partially-transparent to a spectrum of light that may be converted to electric current by solar cell 120. Of course, the term “partially-transparent” includes those materials that are fully transparent to the entire spectrum or to a portion thereof. Reflective surface 114 may receive light of this spectrum and reflect the light toward second surface 124 of solar cell 120.

Partially-transparent portion 112 is in direct thermal contact with first surface 122 and second surface 124. Such contact may provide improved conduction of heat from solar cell 120 and/or an improved optical path to surfaces 122 and 124 of solar cell 120. Such contact may also provide improved relief of heat-induced strain on solar cell 120. In some embodiments, the direct thermal contact comprises physical contact between portion 112 and one or both of first surface 122 and second surface 124. According to some embodiments, a silicone or other flexible gel (not shown) is disposed between partially-transparent portion 112 and one or both of surfaces 122 and 124. The gel may be index matched with a material of portion 112 to present light 140A with a substantially-seamless optical path.

A composition of portion 112 may therefore be selected based on its heat transfer coefficient, transparency, and coefficient of thermal expansion (CTE) with respect to solar cell 120, as well as material cost, manufacturability, etc. Embodiments of partially-transparent portion 112 may include, but are not limited to, a gas, a liquid, a solid, crystalline-structured materials, diamond, sapphire, and/or glass.

Optical element 110 may exhibit any shape and/or include any components for receiving light 140A and directing a first portion of light 140A to first surface 122 of solar cell 120 and a second portion of light 140A to second surface 124 of solar cell 120. Some embodiments of optical element 120 utilize total internal reflection to assist in directing the first portion and/or the second portion as described.

According to some embodiments, optical element is configured to concentrate light 140A before light 140A reaches surface 122 and/or surface 124. Optical element 110 may comprise an entrance aperture suited to receive an angular bundle of rays from a preceding optical stage (e.g., concentrating solar collector 130). Optical element 110 may direct light toward surfaces 122 and 124 at an angle less than or equal to a preferred acceptance angle of solar cell 120 (e.g., ˜60 degrees for conventional solar cells).

Optical element 110 may comprise a dielectric-filled and/or multi-stage compound parabolic concentrator (CPC), cone concentrator, or paraboloid of revolution in some embodiments. Properties and examples of these shapes are provided at least in pages 45-89 of Non-Imaging Optics, by Winston et al. (2005). A shape of optical element 110 may be optimized based on the edge ray principal described therein.

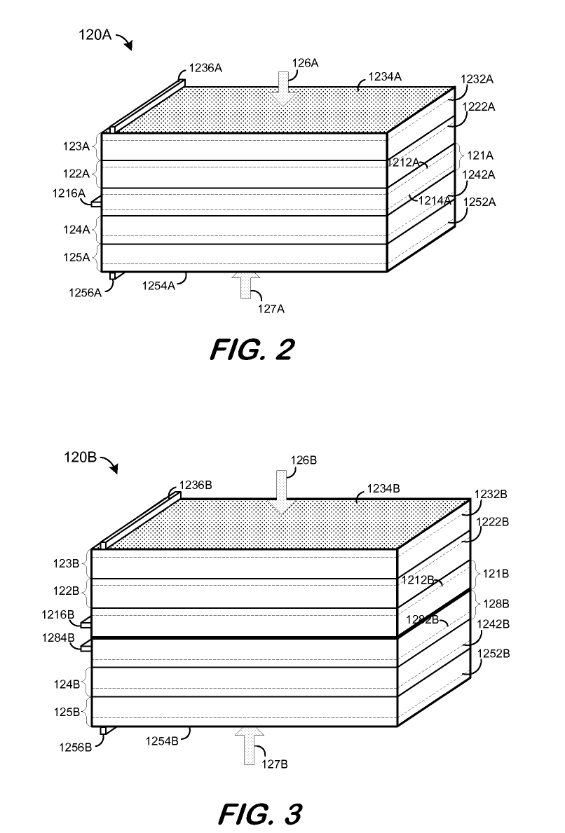

Bifacial solar cell 120 may comprise a bifacial monojunction or multijunction solar cell. FIGS. 2 and 3 are cutaway plan views of bifacial multijunction solar cells 120A and 120B as described in commonly-assigned, co-pending U.S. patent application Ser. No. (Atty. Docket No. SF-P125), entitled Bifacial Multijunction Solar Cell and filed on even date herewith. Some embodiments may include any suitable bifacial solar cell.

Solar cell 120A includes photovoltaic cells 121A through 125A composed of respective photovoltaic materials. Each of cells 121A through 125A includes a respective p-n junction, specifically p-n junction 1212A and 1214A within photovoltaic cell 121A, p-n junction 1222A within photovoltaic cell 122A, p-n junction 1232A within photovoltaic cell 123A, p-n junction 1242A within photovoltaic cell 124A, and p-n junction 1252A within photovoltaic cell 125A.

First surface 1234A and second surface 1254A are disposed on opposite sides of device 120A. First surface 1234A and second surface 1254A are at least partially transparent. In this regard, photons of at least part of the sunlight spectrum may pass through first surface 1234A and second surface 1254A during operation of device 120A.

Each of the photovoltaic materials of photovoltaic cells 121A through 125A is associated with a bandgap. The bandgap is an energy difference between the top of a material's valence band and the bottom of its conduction band. A first bandgap associated with the photovoltaic material of photovoltaic cell 121A is less than a second bandgap associated with the photovoltaic material of photovoltaic cell 122A, which in turn is less than a third bandgap associated with the photovoltaic material of photovoltaic cell 123A. Similarly, a bandgap of photovoltaic cell 125A is greater than a bandgap of photovoltaic cell 124A, which is greater than the bandgap of photovoltaic cell 121A.

Surface 1234A may receive light 126A having any suitable intensity or spectra. Some photons of light 126A are absorbed by photovoltaic cell 123A. More particularly, photons of light 126A which exhibit energies greater than the bandgap of photovoltaic cell 123A pass through an n-region of photovoltaic cell 123A, enter a p-region of photovoltaic cell 123A, and liberate electrons therein. The liberated electrons may be pulled into the n-region by means of an electric field established by and along p-n junction 1232A.

Photons of light 126A which exhibit energies less than the bandgap of photovoltaic cell 123A may pass through photovoltaic cell 123A and into a p-region of photovoltaic cell 122A. Any of such photons which exhibit energies greater than the bandgap of photovoltaic cell 122A may liberate electrons in the p-region. The photons which exhibit energies less than the bandgap of photovoltaic cell 122A but greater than the bandgap of photovoltaic cell 121A may pass through photovoltaic cell 122A and into a p-region of photovoltaic cell 121A to liberate electrons therein. A similar process occurs with respect to light 127A entering surface 1254A of photovoltaic cell 125A.

Common conductive contact 1216A is electrically coupled to photovoltaic cell 121A, and negative conductive contacts 1236A and 1256A are coupled to photovoltaic cell 123A and to photovoltaic cell 125A, respectively. The conductive contacts may be coupled to external circuitry to provide electrical current generated by device 120A thereto. Specifically, contacts 1236A and 1256A collect electrons generated by device 120A and contact 1216A provides a return path therefor.

Embodiments are not limited to the depicted contact structure. For example, contacts 1236A and 1256A may be disposed over surface areas 1234A and 1254A, respectively, in a grid-like pattern to facilitate suitable collection of the generated electrons.

Any suitable materials that are or become known may be incorporated into device 120A. For example, each of the first through third photovoltaic materials may comprise elements from Periods II-VI or from Periods III-V of the periodic table. According to some embodiments, photovoltaic cell 121A may comprise Ge, GaAs, Si, or any other suitable substrate. Some examples of photovoltaic cells 122A and 124A include GaAs and GaInP, while examples of photovoltaic cells 123A and 125A include AlInP, GaInP and AlGaInP. According to some embodiments, the photovoltaic material of photovoltaic cell 122A is identical to the photovoltaic material of photovoltaic cell 124A, and the photovoltaic material of photovoltaic cell 123A is identical to the photovoltaic material of photovoltaic cell 125A.

Solar cell 120A may include unshown active, dielectric, metallization and other layers and/or components that are or become known, and may be fabricated using any suitable methods that are or become known. According to conventional multijunction solar cell design, tunnel diode layers may be disposed between each adjacent photovoltaic cell. Each photovoltaic cell may include several layers of various photovoltaic compositions and dopings. The various layers of solar cell 120A may be formed using molecular beam epitaxy and/or metal organic chemical vapor deposition.

In some embodiments, partially-transparent dielectric portion 112 passes electrical connections to solar cell 120 and/or includes void for encapsulating other desired elements. Such elements are omitted from the discussion herein for the sake of clarity.

FIG. 3 is a cutaway plan view of solar cell 120B according to some embodiments. Solar cell 120B includes photovoltaic cells 121B through 126B composed of respective photovoltaic materials. Solar cell 120B may be characterized as two conventional monofacial cells having substrates bonded to one another. The elements of FIG. 3 may be embodied as described above with respect to similarly-numbered elements of 120A.

Photovoltaic cell 121B may comprise a substrate material (e.g., Ge) including p-n junction 1212B. Photovoltaic cells 122B and 123B include p-n junctions 1222B and 1232B, and comprise photovoltaic material exhibiting increasingly larger bandgaps as described above.

Similarly, photovoltaic cell 128B may comprise a substrate material including p-n junction 1282B, and photovoltaic cells 124B and 125B include p-n junctions 1242B and 1252B. The bandgaps of photovoltaic cells 128B, 124B and 125B increase progressively toward surface 1254B. Using the mechanisms described above, light 126B received at surface 1234B may be converted to electrical current by photovoltaic cells 123B, 122B and 121B. Light 127B received at surface 1254B, on the other hand, may be converted to electrical current by photovoltaic cells 125B, 124B and 128B.

Photovoltaic cells 123B, 122B and 121B are electrically isolated from photovoltaic cells 125B, 124B and 128B. Positive conductive contact 1214B is electrically coupled to photovoltaic cell 12 1B, and negative conductive contact 1236B is coupled to photovoltaic cell 123B. Positive conductive contact 1284B is electrically coupled to photovoltaic cell 128B, and negative conductive contact 1256B is coupled to photovoltaic cell 125B. Accordingly, electrical current generated by photovoltaic cells 123B, 122B and 121B is carried by conductive contacts 1214B and 1236B, and electrical current generated by photovoltaic cells 125B, 124B and 128B is carried by conductive contacts 1284B and 1256B.

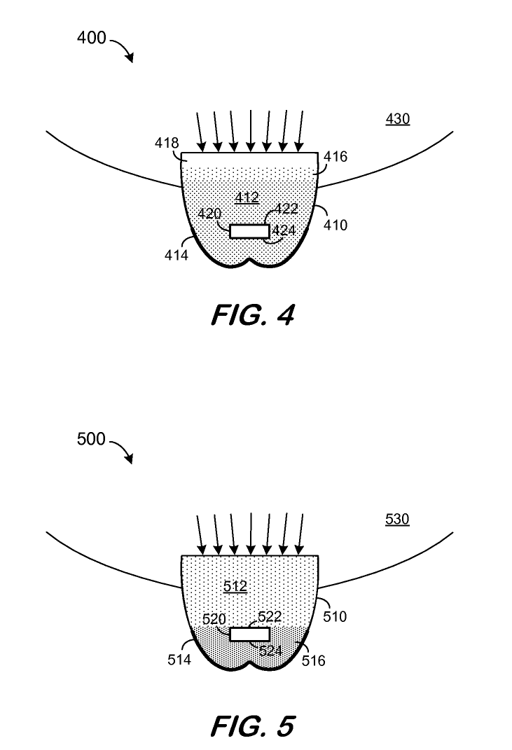

FIG. 4 is a close-up cutaway view of a portion of system 400 according to some embodiments. System 400 includes optical element 410 in which bifacial solar cell 420 is disposed. Optical element 410 is configured to receive light from solar collector 430.

Optical element 410 includes partially-transparent dielectric portion 412 in direct thermal contact with first surface 422 and second surface 424 of solar cell 420. Optical element 410 includes reflective surface 414 to reflect received light toward second surface 424.

Optical element 410 also includes partially-transparent dielectric portions 416 and 418. Portions 412, 416 and 418 may be composed of different materials. In this regard, FIG. 4 illustrates that the optical element 410 is not homogenous in some embodiments. The materials of portions 412, 416 and 418 may be selected for their suitability based on their cost, refractive indexes, thermal conductivity and/or thermal expansion characteristics.

FIG. 5 is a close-up cutaway view of a portion of system 500 according to some embodiments. System 500 includes optical element 510 in which bifacial solar cell 520 is disposed and including reflective surface 514 to reflect received light toward second surface 524 of solar cell 520. System 500 also includes solar collector 530 to provide light to optical element 5 10.

Optical element 510 includes partially-transparent dielectric portion 512 in direct thermal contact with first surface 522 of solar cell 520 and partially-transparent dielectric portion 516 in direct thermal contact with second surface 524. Portions 512 and 516 may be composed of different materials. In some embodiments, the optical transmission characteristics of portion 512 are particularly suited for transmission of light from collector 530 to surface 522, while the optical transmission characteristics of portion 516 are particularly suited for transmission of light to reflective material 514 and onto to surface 524. Portion 516 may also provide for better thermal conductivity of heat away from solar cell 520.

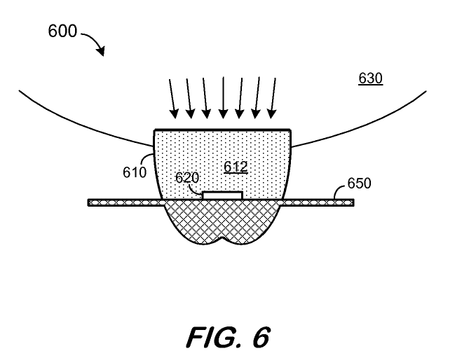

FIG. 6 is a close-up cutaway view of a portion of system 600 according to some embodiments. System 600 includes optical element 610 in which bifacial solar cell 620 is disposed as described with respect to optical element 110 of system 100. Optical element 610 may comprise any of the alternatives illustrated and/or described herein.

System 600 also includes heat spreader 650 coupled to a lower surface of optical element 610. In operation, optical element 610 may conduct heat from solar cell 620 to heat spreader 650. Heat spreader 650 may comprise any suitable composition, including but not limited to aluminum. Heat spreader 650 may be coupled to optical element 610 using a compound selected to relieve strain induced by temperature change. For example, in a case that portion 612 comprises glass (i.e., low CTE) and heat spreader 650 comprises aluminum (high CTE), heat spreader 650 may be coupled to optical element 610 using silicone. Such a compound may allow for a thin bondline, thereby reducing series thermal resistance between portion 612 and heat spreader 650.

As shown in FIG. 6, heat spreader 650 exhibits a shape inverse to the three-dimensional shape of the surface of portion 612 to which heat spreader 650 is coupled. Such conformity may also reduce the series thermal resistance between portion 612 and heat spreader 650 and consequently improve cooling of solar cell 620.

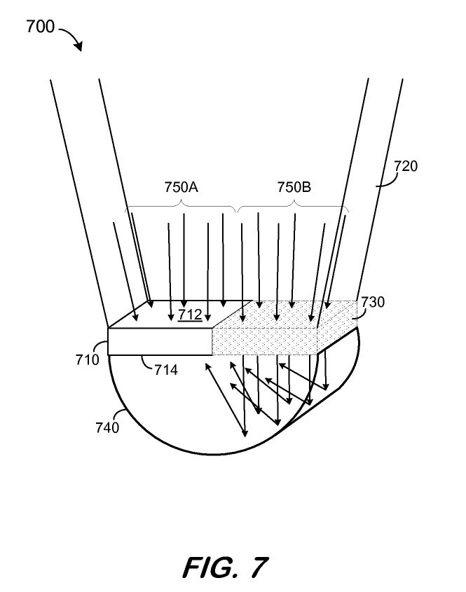

FIG. 7 is a close up perspective view of system 700. System 700 includes bifacial solar cell 710, optical rod 720, optical interface 730 and partially-transparent optic 740. Solar cell 710 includes partially-transparent surface 712 and partially-transparent surface 714.

Optical rod 720 may receive concentrated light from an unshown concentrating system, and may provide some degree of concentration as well. Optical interface 730 may comprise a gel or other material index-matched with optical rod 720 and optic 740. Optic 740 may comprise a half-cylinder bonded to solar cell 710 via optical interface 730 and/or using a dedicated bonding compound (not shown). A direct thermal contact with the outermost edge of solar cell 710 may be made to enable an additional heat transfer path.

In operation, light 750A passes from optical rod 720 through surface 712 of solar cell 710 for conversion to electrical current via the mechanisms described above. Light 750B passes through optical interface 730 and reflects off the curved surface of optic 740. The reflection may be accomplished through total internal reflection and/or through reflection off of a reflective material disposed on the curved surface. The reflected light enters solar cell 710 through surface 714.

A material of optic 740 may be selected for its thermal conductivity (i.e., to promote heat dissipation from solar cell 710) and/or CTE (i.e., to reduce heat-induced strain on solar cell 710), as well as for its optical properties. Optic 740 may comprise glass, sapphire, diamond, and/or other materials. Optic 740 may be further coupled to a heat spreader such as heat spreader 650 described above. Such a heat spreader may exhibit a shape inverse to the three-dimensional shape of the surface of optic 740 to which the heat spreader is coupled.

The several embodiments described herein are solely for the purpose of illustration. Embodiments may include any currently or hereafter-known versions of the elements described herein. Therefore, persons skilled in the art will recognize from this description that other embodiments may be practiced with various modifications and alterations.

What is claimed is:

1. An apparatus comprising:
a solar cell comprising:
a partially-transparent first surface;
a partially-transparent second surface;
a first p-n junction between the first surface and the second surface;
a second p-n junction between the first surface and the second surface; and
a third p-n junction between the first surface and the second surface,
wherein a first bandgap associated with the first p-n junction is greater than a second bandgap associated with the second p-n junction, and
wherein a third bandgap associated with the third p-n junction is greater than the second bandgap associated with the second p-n junction; and
an optical element comprising a first partially-transparent dielectric portion in direct thermal contact with the first surface and the second surface,
wherein the optical element is configured to receive light, to direct a first portion of the received light to the first surface, and to direct a second portion of the received light to the second surface.

2. An apparatus according to claim 1, wherein the optical element is further configured to concentrate the received light,
wherein the first portion of the received light comprises a first portion of the concentrated light, and
wherein the second portion of the received light comprises a second portion of the concentrated light.

3. An apparatus according to claim 1, further comprising:
a heat spreader coupled to a surface of the first partially-transparent dielectric portion of the optical element.

4. An apparatus according to claim 3, wherein the surface of the first partially-transparent dielectric portion exhibits a three-dimensional shape, and
wherein the heat spreader exhibits a shape inverse to the three-dimensional shape.

5. An apparatus according to claim 4, wherein the first partially-transparent portion comprises sapphire.

6. An apparatus according to claim 1, wherein the first partially-transparent portion comprises sapphire.

7. An apparatus according to claim 1, further comprising:
a concentrating solar collector configured to receive sunlight, to concentrate the received sunlight, and to direct the concentrated sunlight to the optical element.

8. An apparatus according to claim 1, wherein the optical element further comprises a second substantially-transparent dielectric portion in contact with the first substantially-transparent dielectric portion.

9. An apparatus according to claim 1, wherein the first partially-transparent dielectric portion comprises a solid.

10. A method comprising:
acquiring a solar cell comprising:
a partially-transparent first surface;
a partially-transparent second surface;
a first p-n junction between the first surface and the second surface;
a second p-n junction between the first surface and the second surface; and
a third p-n junction between the first surface and the second surface,
wherein a first bandgap associated with the first p-n junction is greater than a second bandgap associated with the second p-n junction, and
wherein a third bandgap associated with the third p-n junction is greater than the second bandgap associated with the second p-n junction; and
fabricating an optical element comprising a first partially-transparent dielectric portion in direct thermal contact with the first surface and the second surface,
wherein the optical element is configured to receive light, to direct a first portion of the received light to the first surface, and to direct a second portion of the received light to the second surface.

11. A method according to claim 10, wherein the optical element is further configured to concentrate the received light,
wherein the first portion of the received light comprises a first portion of the concentrated light, and
wherein the second portion of the received light comprises a second portion of the concentrated light.

12. A method according to claim 10, further comprising:
coupling a heat spreader to a surface of the first partially-transparent dielectric portion of the optical element,
wherein the surface of the first partially-transparent dielectric portion exhibits a three-dimensional shape, and
wherein the heat spreader exhibits a shape inverse to the three-dimensional shape.

13. A method according to claim 10, further comprising:
coupling the optical element to a concentrating solar collector configured to receive sunlight, to concentrate the received sunlight, and to direct the concentrated sunlight to the optical element.

14. A method according to claim 10, wherein the optical element further comprises a second substantially-transparent dielectric portion in contact with the first substantially-transparent dielectric portion.

15. A method according to claim 10, wherein the first substantially-transparent dielectric portion comprises a solid.
